(19) United States
(12) Patent Application Publication
(10) Pub. No.: US 2002/0084107 A1
(43) Pub. Date: Jul. 4, 2002

(54) High frequency semiconductor chip package and substrate

(75) Inventors: Tae-Sub Chang, Seoul (KR); Dong-Ho Lee, Seoul (KR)

Correspondence Address: MARGER JOHNSON & McCOLLOM, P.C., 1030 S.W. Morrison Street, Portland, OR, 97205, US

(73) Assignee: Samsung Electronics Co., Ltd., Suwon-city (KR)

(21) Appl. No.: 10/040,868

(22) Filed: Dec. 27, 2001

(30) Foreign Application Priority Data
Dec. 28, 2000 (KR) 2000-83571

(51) Int. Cl. H05K 1/11

(52) U.S. Cl. 174/262; 174/261; 174/267; 174/266; 257/700; 257/698; 29/846

(57) ABSTRACT

A substrate is configured to electrically interconnect a semiconductor chip to an external device. The substrate preferably includes a ground plane that is electrically interconnected to a ground power of the semiconductor chip. An insulating layer is attached to the ground plane. A pattern layer is attached to the insulating layer. The pattern layer includes signal patterns that communicate electrical signals with the semiconductor chip and ground patterns that are electrically interconnected to the ground plane. The ground patterns can include bonding lands to provide electrical connection to the semiconductor chip. The bonding lands can be further provided with first via holes that electrically interconnect the ground patterns to the ground plane.

This application claims priority from Korean Patent Application No. 2000-83571, filed Dec. 28, 2000, the contents of which are hereby incorporated herein by reference in their entirety.

### BACKGROUND OF THE INVENTION

1. Technical Field of the Invention

This invention relates to semiconductor packaging technology, and more particularly to semiconductor packages and substrates used therein, which can ensure reliable electrical performance characteristics for semiconductor integrated circuit (IC) devices operating at high frequencies.

2. Description of Related Art

Semiconductor IC chips are generally packaged to physically protect the chips from harmful external environments. Because the operational requirements of modern semiconductor memory chips demand lower power operation at higher speed, semiconductor packages must evolve beyond simply providing physical protection. The packages are also configured to be in electrical communication with external devices. To ensure reliable, high performance memory chip operation, semiconductor packages should have optimal electrical characteristics.

In conventional, low-speed memory devices, deterioration in performance due to parasitic parameters of both the package and the package substrate RLC circuit have not been considered critical or significant. Certain high-speed memory devices, such as Rambus DRAMs (which operate at data rates of up to 800 million transfers/second) and Double Data Rate (DDR) RAMs, however, exhibit all the properties of an RF signal. In these memory devices, therefore, parasitic phenomena such as reflections and crosstalk become significant. In addition, at these high speeds, parasitic parameters due to the package construction may also significantly degrade performance of the memory device, potentially causing failures.

Three electrical parameters, including capacitance, inductance, and resistance, are important considerations in every packaging concept. Resistance may cause signal line DC drops while contributing to charging delays in RC networks. The capacitance of a channel is mainly responsible for signal loss and propagation delay and can be reduced by decreasing the physical dimensions of the RC network. Inductance also contributes to switching noise and delays associated with packages. A low dielectric constant helps to reduce both signal delay and crosstalk. Crosstalk is the coupled noise from busy signal paths to idle paths caused by mutual capacitive and inductive coupling.

A more stable power supply and decreased crosstalk and signal skew can be obtained by reducing inductance. Capacitance and inductance may be expressed in static parasitic parameters including inductance of signal trace, mutual capacitance, and mutual inductance; and in dynamic parasitic parameters such as SSO (Simultaneously Switching Output) noise and crosstalk. SSO noise is one of the fundamental problems in high-speed semiconductor devices. As shown in Formula 1, inductance may cause an unwanted voltage drop (ΔV) in proportion to the variation of current (i) with respect to time (t).

ΔV=L_{I}(di/dt) (Formula 1)

In Formula 1, L_{I} is an effective loop inductance between the signal trace and the ground trace. The loop inductance is caused by an image current returning to form a loop when a current flows in a signal trace. The return image current flows along a minimum resistance path when frequency is low, but flows along a minimum inductance path when frequency is high. The magnitude of the loop inductance is the loop area formed by the applied current and the image return current. The loop inductance is a kind of noise, which produces an unwanted voltage drop. Accordingly, in order to secure an adequate timing margin, along with stable power and signal voltage, the voltage drop ΔV due to the loop inductance LI must be kept to a minimum.

Crosstalk is caused by the mutual capacitance and mutual inductance between neighboring signal traces. The amount of crosstalk increases as the distance between the neighboring traces decreases. The degree of coupling of neighboring traces is related to the distance from each signal trace to the ground trace as well as the parallel length of the signal traces. As coupling increases, capacitance in the signal trace increases and signal transfer velocity decreases. This can result in a glitch in the signal trace. The industry would therefore be benefited by a package that maintains minimal capacitance in signal traces and decreases the loop inductance between a signal trace and a ground trace.

### SUMMARY OF THE INVENTION

The present invention provides a semiconductor package that exhibits stable electrical characteristics at higher operating speeds, as well as a method for manufacturing the same.

The present invention also decreases the loop inductance caused by patterns formed in a package substrate and minimizes the current return path.

According to one embodiment of the present invention, a substrate is configured to electrically interconnect a semiconductor chip mounted thereon to an external device. The substrate includes a ground plane electrically interconnected to a ground power of the semiconductor chip. An insulating layer is attached to the ground plane. A pattern layer is attached to the insulating layer. The ground plane, insulating layer, and pattern layer are stacked on top of each other.

The pattern layer includes signal patterns that communicate electrical signals with the semiconductor chip and ground patterns that are electrically interconnected to the ground plane. The ground patterns include bonding lands with bonding wires attached thereto. The bonding wires are electrically connected to the semiconductor chip, and the bonding lands are provided with a first via hole so as to electrically interconnect the ground patterns to the ground plane.

The first via hole (or first ground via) is preferably a blind via hole that can be completely filled with or partially plated with metal. Depending on the manufacturing process for the substrate, the first ground via may be blinded with the pattern layer. The signal and ground patterns preferably include solder ball land patterns to which a plurality of solder balls are attached, and the ground pattern may further include a second ground via electrically interconnected to the ground plane. The insulating layer may be a polyimide tape and the metal is preferably copper.

A semiconductor package according to a preferred embodiment of the present invention includes a semiconductor IC chip attached to the substrate and electrically interconnected to the substrate. The semiconductor IC chip is attached to the substrate using an elastic adhesive. The package is preferably a wafer level package.

### BRIEF DESCRIPTION OF THE DRAWINGS

The foregoing and other features and advantages of the present invention will be more readily apparent from the following detailed description of preferred embodiments, made in conjunction with the accompanying drawings, in which:

FIG. 1 is a cross sectional view of a semiconductor chip package according to the present invention.

FIG. 2 is a plan view of a pattern layer suitable for use in a substrate of a semiconductor chip package according to the present invention.

FIG. 3 is a plan view of a ground layer suitable for use in a substrate of a semiconductor chip package according to the present invention.

FIG. 4 is a schematic perspective view of a substrate, illustrating advantageous effects of the present invention.

FIG. 5 is a plan view illustrating a current return path in a structure according to the present invention.

FIG. 6 is a plan view showing a current return path in a conventional structure.

### DETAILED DESCRIPTION OF PREFERRED EMBODIMENTS

Following is a detailed description of preferred embodiments of the present invention. With respect to the accompanying drawings, it should be noted that the figures are not drawn to scale. Furthermore, with respect to the following description, it should be noted that although various preferred embodiments will be described, various other embodiments of the present invention, which are not specifically illustrated, will be apparent to those of ordinary skill in the art.

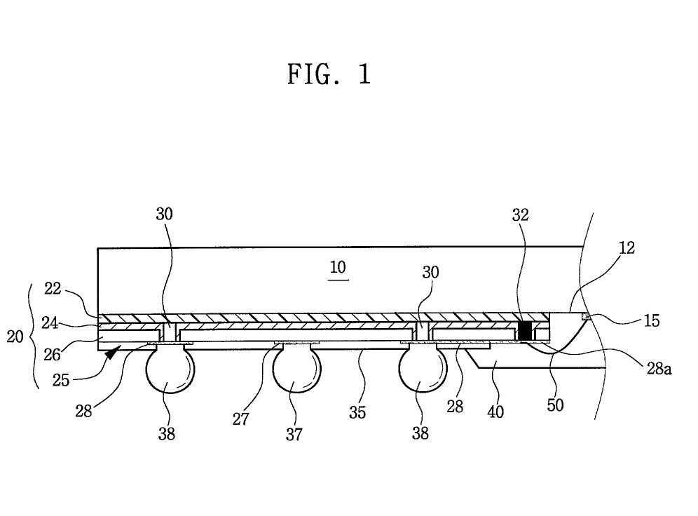

FIG. 1 is a partial cross sectional view of a multi-layered substrate, wire bonded grid array (WBGA) package according to one embodiment of the present invention. In this WBGA, a semiconductor chip 10 is electrically interconnected to a substrate 20 through bonding wires 50. The semiconductor chip 10 is electrically interconnected to an external device (possibly including a computer system motherboard) through a plurality of solder balls 37, 38 attached to an exposed surface of the substrate 20.

The semiconductor chip 10 is bonded face-down to the package substrate 20. In other words, an active surface 12, where a number of electrode pads 15 are formed, faces in the direction of the substrate 20. The package substrate 20, for example, includes an elastic layer 22, a ground plane 24, an electrically insulating layer (e.g., a polyimide tape) 26, signal patterns 27, and ground patterns or power patterns 28. A pattern layer 25, which includes the signal patterns 27 and the ground patterns 28, can be formed, for example, either by photo-etching a deposited copper layer or by electroplating copper. The copper pattern layer 25 may further be covered with a barrier layer made of nickel/gold. In the substrate structure 20 shown, the ground plane 24, the insulating layer 26, and the pattern layer 25 are arranged on each other in this order.

The ground patterns 28 and the ground plane 24 are electrically interconnected through via holes 30, 32. The signal pattern 27 is electrically interconnected to electrode pads 15 of the semiconductor chip 10 by interconnection means such as bonding wires 50. The exposed region of the active surface of the semiconductor chip 10 is covered with an encapsulant 40.

The signal patterns 27 and the ground patterns 28 are partially or selectively covered with a Photo-Sensitive Resistor (PSR) 35 to form solder ball lands. Solder balls 37, 38 are attached to the solder ball lands. The solder balls 37, 38 provide electrical contacts between the semiconductor chip 10 and an external device. The signal solder balls 37 are attached to the signal pattern 27, while the ground solder balls 38 are attached to the ground pattern 28. The ground pattern 28 is electrically interconnected to the ground plane 24 through the ground via holes 30, 32. The ground via hole 32, formed in the bonding land region 28a, is a blind via. The bonding wires 50 can be stitch bonded to the bonding land region 28a.

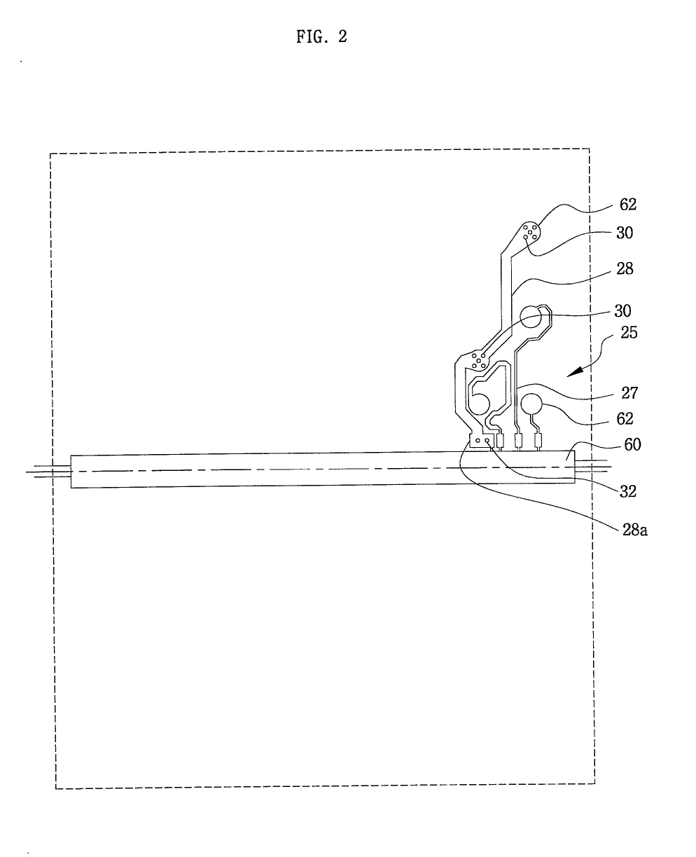

According to another aspect of the present invention, the package substrate 20 can be manufactured according to the following process. A copper layer is deposited on one side of the polyimide tape 26. The copper layer forms the ground plane 24. Via holes 30, 32 are formed through the polyimide tape 26 and are filled or plated with copper. Another copper layer is deposited on a surface of the polyimide tape 26 opposite the ground plane 24. This second copper layer provides the pattern layer 25. The pattern layer 25 is formed by photo-etching the deposited copper layer with a mask having patterns that correspond to the signal pattern 27 and ground pattern 28. The pattern layer 25 may be plated with a nickel/gold metal. An opening (such as opening 60 of FIG. 2) for the electrode pads is formed using a punching process.

In this embodiment, the electrode pads 15 are formed centrally on the active surface of the semiconductor chip. By selectively depositing a PSR 27 on the pattern layer 25, solder ball lands are formed. Also in this embodiment, the via hole 32, formed in the wire bonding land region 28a, is blinded by metal patterns, thereby making direct wire bonding to the via 32 possible and further improving the reliability of the wire bonding.

According to yet another embodiment of the present invention, another process of manufacturing the package substrate 20 is provided. In this embodiment, copper layers are deposited on both sides of the polyimide tape 26. Via holes 30, 32 are formed and filled or plated with copper. One of the copper layers is used to provide the ground plane 24. The other copper layer is photo-etched and patterned, using a mask with patterns corresponding to the signal pattern 27 and the ground pattern 28, to provide the pattern layer 25. The pattern layer 25 may be plated with nickel/gold. An opening (such as the opening 60 of FIG. 2) is formed through a punching process to expose the electrode pads of the semiconductor chip. Solder ball lands are formed by selectively depositing a PSR 27 on the pattern layer 25.

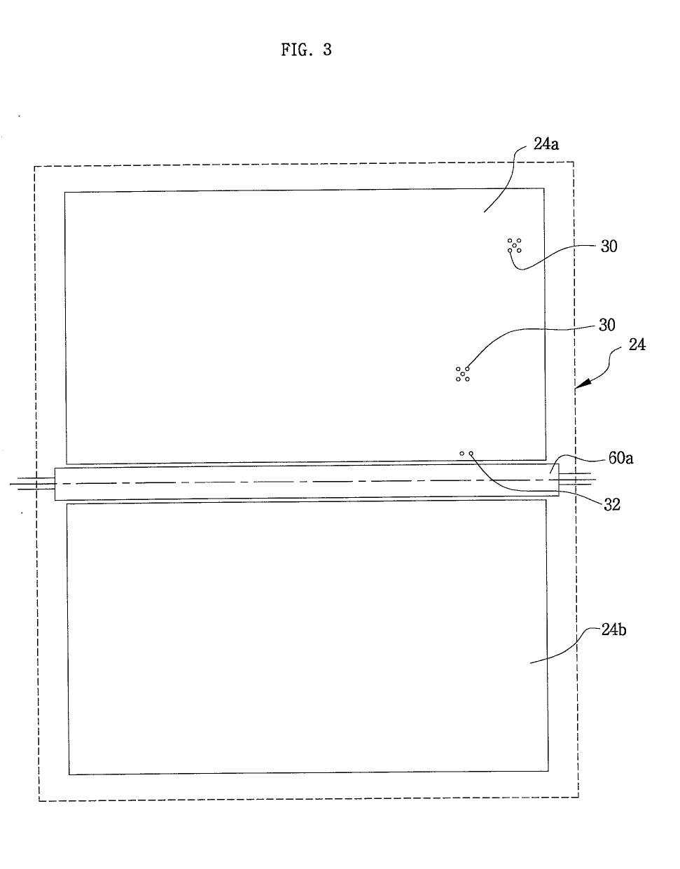

FIG. 2 is a plan view of a pattern layer 25 suitable for use in the package substrate 20 of the present invention. FIG. 3 is a plan view of a ground plane 24 suitable for use in the package substrate of the present invention. Parts of the patterns are shown in both FIG. 2 and FIG. 3 for clarity.

Referring to FIG. 2, the pattern layer 25 includes the signal pattern 27 and the ground pattern or power pattern 28 and has an opening centrally disposed to expose the electrode pads 15 of the semiconductor chip 10. The signal pattern 27 and the ground pattern 28 include solder ball lands 62 to which signal solder balls 37 and ground solder balls 38 are attached, respectively. The solder ball lands for the ground pattern 28 are provided with a plurality of via holes 30, 32. The blind via hole 32 is formed in the bonding land 28a of the ground pattern 28.

In FIG. 3, the ground plane 24 comprises two conductive planes 24a and 24b, separated by the central opening 60a. The plurality of via holes 30, 32 are formed in the conductive planes 24a and 24b.

The package substrate, constructed according to a preferred embodiment of the present invention, improves the high frequency characteristics of the package. However, as explained below, there are certain limits on the amount of improvement provided.

1) Self Inductance and Mutual Inductance

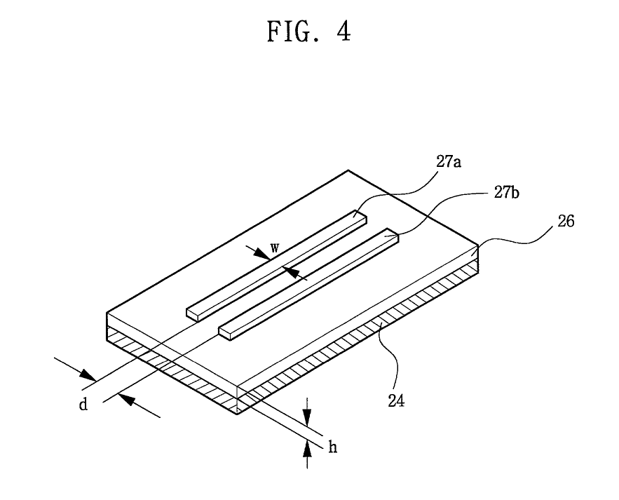

Referring to FIG. 4, the substrate 20 can be viewed as two signal traces 27a, 27b formed on a ground plane 24 and interposed with an insulating layer 26. Self-inductance Ls decreases as the distance ‘h’ between the ground plane 24 and the trace 27 becomes shorter and as the width ‘w’ of the trace 27 increases. This relationship is reflected in Formula 2.

Lₛ∝h/w (Formula 2)

Mutual inductance Lm decreases as the distance ‘d’ between the traces 27a, 27b increases and as the distance ‘h’ to the ground plane 24 decreases. This relationship is shown in Formula 3.

Lm∝h/d (Formula 3)

Accordingly, both the self-inductance Ls and the mutual inductance Lm of the traces can be decreased by positioning the ground plane 24 as close to the signal patterns 27 as possible.

2) Simultaneously Switching Output (SSO) Noise

As shown in Formula 1, in high frequency semiconductor IC devices, a voltage drop occurs when multiple signals simultaneously switch, causing a reduction in power level, a decline in driving capacity of the device, and signal delay. To prevent SSO noise, loop inductance should be minimized.

The loop inductance of a high-frequency IC device is determined by the area of an imaginary loop formed by a current flowing in a signal trace and a return current flowing in an adjacent ground trace. Because the return current tends to flow along a path of minimum inductance, the ground trace closest to the signal trace provides the path of the return current. If the ground plane is disposed just below the signal pattern layer, the loop area, and hence the loop inductance, is minimized. The equation for determining loop inductance is expressed in Formula 4, where L_{I} is a loop inductance, L_{SIG} is a self inductance of a signal trace, L_{GND} represents a self inductance of a ground path, and L_{SIG}_{_{—}}_{GND} is a mutual inductance of the signal trace and the ground path.

L_{I}=(L_{SIG}+L_{GND}−2L_{SIG}_{_{—}}_{GND}) (Formula 4)

As is apparent from Formulas 2 and 3, when a ground path is formed in a plate structure and located just below the signal line, the self inductances of the signal line L_{SIG} and the ground path L_{GND} are decreased while the mutual inductance of the signal line the ground path L_{SIG}_{_{—}}_{GND} is increased. This results in a decrease of the loop inductance L_{I}. Further, the plate structured ground path can provide stable feedback current path for all signal lines.

3) Crosstalk

In order to understand the crosstalk phenomena resulting from the mutual inductance and mutual capacitance between neighboring signal traces, two cases should be considered. In a first case, current flows in an identical direction in two signal lines having (referred to as an “even mode”). In a second case, current in two signal lines flows in opposite directions, i.e., current in each of the signal lines flows with a phase shift of 180 degrees relative to the other signal line (referred to as an “odd mode”). When currents start flowing in the neighboring signal traces, the generated electric field is different depending on whether it flows in the even or the odd mode. As a result, the propagation velocity of the signal traces differs according to the current mode. The discrepancy in the propagation velocity may cause a deformation in signal waveforms and an increase in the coupling noise. Moreover, the difference in the two modes reduces the timing margin of a system. To secure stable signal input and output and enough timing margin in a high-speed IC device, the difference between the propagation velocity in the even and odd modes must be kept as small as possible.

One method to reduce the difference between the two propagation velocities is to decrease the mutual parameters. As shown in Formula 3, the mutual inductance decreases as the distance to the ground becomes smaller. On the other hand, as the distance to the ground decreases, the mutual capacitance has an equal or slightly smaller value when compared with a standard structure where the signal trace and the ground trace exist in a single plane. Therefore, for the purpose of minimizing the difference in the propagation velocity of the even and odd modes, it is beneficial to have the ground plane located just below the signal pattern layer.

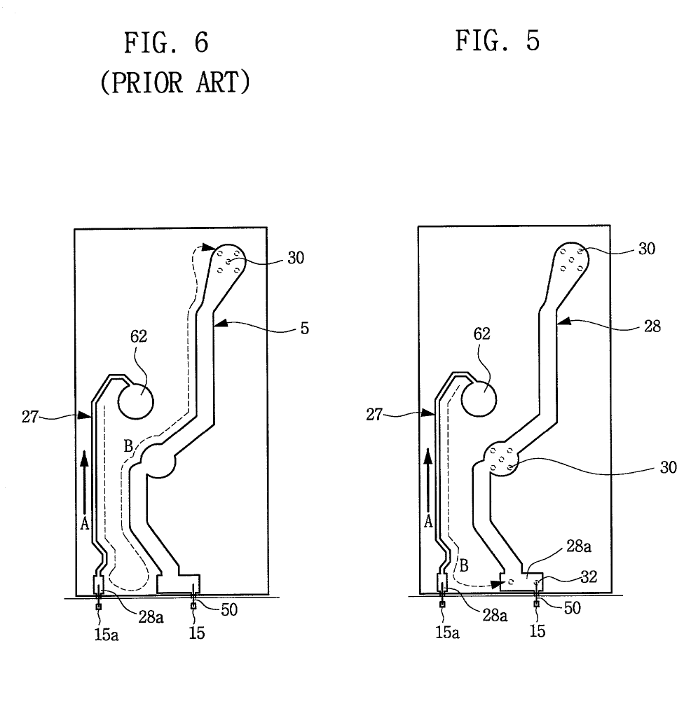

An additional improvement can be obtained through the optimization of the current return path. FIG. 5 shows the return path of an image current according to yet another embodiment of the present invention. Referring to FIG. 5, when an electrical signal is applied to an electrode pad 15athat is connected to the signal pattern 27, a signal current flows along a direction denoted by the reference symbol “A”. As a result, an image current flows out or returns to the ground plane 24 through the ground via 32 along a direction denoted by reference symbol “B”. This return current path is significantly shorter than that of the conventional structure, as shown in FIG. 6. Accordingly, using the structure of this preferred embodiment, the image current takes the shortest return route through the ground via 32 in close proximity to the electrode pad 15, and the return loop is formed without a long narrow path, which results in a decrease of the loop inductance.

FIG. 6 shows a return current path of the conventional structure. When a signal is applied to an electrode pad 15athat is connected to the signal pattern 27, the signal current flows along a direction denoted by the reference symbol “A” in FIG. 6. An image current therefore flows to the ground plane through the via 30 along a path denoted by the reference symbol “B” in FIG. 6. In this conventional structure, the image current takes a long route to the ground via 30, which is farther from the signal pattern. The overall current loop is formed along the narrow path of the signal pattern 27 and the ground pattern 5. As a result, the loop inductance inevitably increases in the conventional structure.

According to another aspect of the present invention, the blind via 32 may be formed after the ground plane 24, the polyimide tape 26, and the pattern layer 25 are formed but before the signal and the ground patterns 27, 28 are formed on the pattern layer 25. Alternatively, the blind via 32 may be formed after forming the ground plane 24 on the polyimide tape 26, but before forming the pattern layer 25. The blind via is preferably a plated hole that does not completely penetrate the entire substrate, having a surface layer (e.g., the pattern layer 25) electrically interconnected to inner metal layer (e.g., the ground plane 24). Mechanical perforation for the via hole may include laser drilling or a photo-lithography and plasma etching technology. Laser drilling has an advantage in that additional machines or materials are not necessary, productivity is enhanced, and processing time is shorter. Further, laser technology produces very small via holes (0.05 to 0.07 mm in diameter) and therefore is easily applied to high-density, multi-layered substrates.

The inner surface of the perforated via hole is preferably electro-plated with a metal, such as copper. The copper can be plated to the inner surface of the via hole 32 to completely or partially fill the hole. Before electroplating, the inner surface of the via hole 32 can be cleaned by a plasma etching process, for instance.

Although various preferred embodiments of the present invention have been disclosed in the foregoing drawings and written description, these embodiments are exemplary only, and the invention should not be limited thereto. The invention should be interpreted to cover all variations and embodiments coming within the scope of the following claims.

What is claim is:

1. A substrate for electrically interconnecting a semiconductor chip mounted thereon to an external device, the substrate comprising:
a ground plane electrically interconnected to a ground power of the semiconductor chip;
an insulating layer attached to the ground plane; and
a pattern layer attached to the insulating layer, the pattern layer comprising a signal pattern electrically interconnected to the semiconductor chip, and further comprising a ground pattern electrically interconnected to the ground plane,
wherein the ground pattern comprises a bonding land, the bonding land comprising a first via hole configured to electrically interconnect the ground pattern to the ground plane.

2. The substrate according to claim 1, wherein the first via holes comprises a blind via.

3. The substrate according to claim 1, further comprising a bonding wire electrically coupling the semiconductor chip to the bonding land.

4. The substrate according to claim 3, wherein the bonding wire is bonded to the first via hole.

5. The substrate according to claim 1, wherein the first via hole is filled with metal.

6. The substrate according to claim 1, wherein the first via hole has an inner surface plated with metal.

7. The substrate according to claim 1, wherein the signal pattern and the ground pattern comprise solder ball lands to which solder balls are attached.

8. The substrate according to claim 1, wherein the ground pattern further comprises a second via hole that is electrically interconnected to the ground plane.

9. The substrate according to claim 1, wherein the ground plane further comprises a first and a second ground plane separated by a centrally disposed opening.

10. The substrate according to claim 1, wherein the insulating layer is a polyimide tape and wherein the pattern layer and the ground plane each comprise copper.

11. The substrate according to claim 1, wherein the substrate is formed by forming the insulating layer on the ground plane, forming the first via hole within the insulating layer, and forming the pattern layer on the insulating layer.

12. The substrate according to claim 1, wherein the substrate is formed by sequentially stacking the ground plane, the insulating layer, and the pattern layer, and forming the first via hole therein.

13. The substrate according to claim 1, wherein the substrate is adapted for use in wafer level packages.

14. A semiconductor chip package comprising:
a semiconductor chip; and
a substrate configured to electrically interconnect the semiconductor chip mounted thereon with an external device, the substrate comprising:
a ground plane electrically interconnected to a ground power of the semiconductor chip;
an insulating layer attached to the ground plane; and
a pattern layer attached to the insulating layer, wherein the pattern layer comprises a signal pattern configured to communicate electrical signals with the semiconductor chip and a ground pattern electrically interconnected to the ground plane,
wherein the ground pattern comprises a bonding land to provide an electrical connection to the semiconductor chip, the bonding land comprising a first via hole configured to electrically interconnect the ground patterns to the ground plane.

15. A semiconductor chip package according to claim 14, further comprising a bonding wire bonded to the first via hole.

16. A semiconductor chip package according to claim 14, wherein the first via hole is filled with metal.

17. A semiconductor chip package according to claim 14, wherein the first via hole has an inner surface plated with metal.

18. A semiconductor chip package according to claim 14, wherein the signal pattern and the ground pattern comprise solder ball lands to which solder balls are attached.

19. A semiconductor chip package according to claim 14, wherein the ground pattern further comprises a second via hole electrically connected to the ground plane.

20. A semiconductor chip package according to claim 14, wherein the ground plane includes a first and a second ground plane separated by a centrally disposed opening.

21. A semiconductor chip package according to claim 14, wherein an exposed surface of the semiconductor is covered by an encapsulant.

22. A semiconductor chip package according to claim 14, wherein the semiconductor chip is attached to the substrate by an elastic adhesive.

23. A method of forming a semiconductor substrate configured to provide electrical connection between a semiconductor chip and an external device, the method comprising:
forming a ground plane on an insulating layer;
forming a via hole within the insulating layer; and
forming a pattern layer on the insulating layer, the pattern layer comprising a signal pattern and a ground pattern,
wherein the ground pattern comprises a bonding land for providing electrical connection to the semiconductor chip, the bonding land overlying the via hole for electrically coupling the ground pattern to the ground plane.

24. A method according to claim 23, wherein the ground plane and the pattern layer are formed on opposite sides of the insulating layer before forming the via hole.

25. A method according to claim 24, wherein the ground plane is formed on the insulating layer and the via hole is formed through the first insulating layer before the pattern layer is formed on the insulating layer.

26. A method according to claim 25, further comprising reducing a length of a return current path in the substrate by providing the via hole in close proximity with the signal pattern.

27. A method according to claim 26, wherein forming the ground plane comprises forming a first and second ground plane separated by a centrally disposed opening.
